(19) United States
(12) Patent Application Publication
(10) Pub. No.: US 2026/0143771 A1
(43) Pub. Date: May 21, 2026

(54) SINGLE DIFFUSION BREAK STRUCTURE AND METHOD OF MANUFACTURING THE SAME

(71) Applicant: UNITED MICROELECTRONICS CORP., Hsin-Chu City (TW)

(72) Inventor: Chia-Chen Sun, Kaohsiung City (TW)

(73) Assignee: UNITED MICROELECTRONICS CORP., Hsin-Chu City (TW)

(21) Appl. No.: 18/988,945

(22) Filed: Dec. 20, 2024

(30) Foreign Application Priority Data
Nov. 20, 2024 (TW) 113144577

(51) Int. Cl. H10D 64/01; H01L 21/762; H01L 23/522; H10D 30/01; H10D 30/62

(52) U.S. Cl. CPC H10D 64/017; H10D 30/024; H10D 30/62; H10W 10/014; H10W 10/17; H10W 20/42

(57) ABSTRACT

A semiconductor structure with single diffusion break (SDB) is provided in the present invention, including a substrate with a first region and a second region defined thereon, the first region and the second region are adjacent to each other and have respective fins, a STI on the substrate and surrounding the fins, multiple gates crossing over the fins, a dummy gate on the STI between the first region and the second region and spaced apart with the gates, at least one conductive pattern on the dummy gate and connected therewith, and at least one dummy via on the at least one conductive pattern and connected therewith.

### BACKGROUND OF THE INVENTION

### 1. Field of the Invention

The present invention generally relates to a single diffusion break (SDB) structure, more specifically, to a single diffusion break structure on shallow trench isolation (STI) and connected with dummy vias and method of manufacturing the same.

### 2. Description of the Prior Art

Single diffusion break (SDB) or single dummy gate is a type of semiconductor technology whose function is that there is no need to set two dummy gates at the boundary of two semiconductor cells to isolate the two adjacent cells. Compared with traditional double diffusion break (DDB) technology that requires two dummy gates to be set up at the boundary, the single diffusion break technology only needs to set up one dummy gate or diffusion break structure, which can achieve further shrinkage of the semiconductor cell without affecting the device height or underlying components, and at the same time achieve the effect of providing good stress control and reducing process variation during the process.

Generally, single diffusion break or double diffusion break technology uses dummy patterns, such as dummy gates, in the layout to achieve the diffusion breaking effect. Dummy patterns may also improve process quality and process yield, for example, helping to balance exposure and development in the photolithography process, ensuring the clarity and accuracy of other important patterns, and reducing defects by increasing the uniformity of the layout patterns, thereby improving overall yield. These dummy patterns usually do not involve in actual circuit functions, but they play an important role in the process. However, in some practical applications, the dummy via (V0) located in the zeroth metal layer (M0) may form unnecessary conductive paths, causing adjacent active blocks to bridge and leak current.

Take FIG. 1 as an example, which is a schematic layout diagram of a semiconductor circuit with a single diffusion break structure in prior art. In FIG. 1, each active block (AA block) is provided with a plurality of fins F, which extend in a first direction D1 and are spaced apart in a second direction D2. Furthermore, the active block is also provided with a plurality of gates G and a plurality of first conductive patterns MD (also known as metal zero over oxide definition layer (M0OD), abbreviated hereinafter as MD). Both of them extend across the fins F in the second direction D2 and are spaced apart in the first direction D1. Furthermore, in order to isolate different cell regions in a block, a single diffusion break structure SDB will be further formed in the block. In practice, the gate G located at the boundary between two cell areas is usually replaced by a dummy gate as part of the single diffusion break structure SDB, with a shape the same as that of a general gate G, between two first conductive patterns MD at the boundary.

Refer now to FIG. 2, which is a schematic cross-sectional view taken along a section line A-A′ in FIG. 1. In addition to the aforementioned gate G and first conductive pattern MD, the zeroth metal layer M0 will also be provided with a zeroth via V0 and a second conductive pattern MP (also known as the metal zero over polysilicon (M0OP), abbreviated hereinafter as MP). In conventional skill, the zeroth via V0 is generally disposed on and connected with the first conductive pattern MD, and the first conductive pattern MD and the fin F connected below are further connected to an upper first metal layer M1 through the zeroth via V0, and further connected to the BEOL (back-end-of-line) circuit. The second conductive pattern MP is disposed on and connected with the gate G. In some designs, the second conductive pattern MP may also be connected with the adjacent first conductive pattern MD, as shown in FIG. 1. The aforementioned fin F, first conductive pattern MD, zeroth via V0 and the first metal layer M1, etc., can form a conductive path. However, in the case of being a dummy pattern, the existence of the zeroth via V0 will cause the circuit of this block to be conducted to the circuit of the adjacent block through the first metal layer M1, as shown by the path B in FIG. 1, causing the circuits of the two blocks to bridge and leak current. Therefore, those of skilled in the art have to improve the conventional single diffusion break structure in order to solve the problems above.

### SUMMARY OF THE INVENTION

In view of the problems encountered in prior art, the present invention hereby proposes a novel single diffusion break (SDB) structure, which is characterized in that a dummy via is arranged on a single diffusion break structure on a shallow trench isolation (STI), so that the leakage path will be blocked by the single diffusion break structure, thereby solving the leakage issue caused by setting up dummy patterns in conventional skill.

One aspect of the present invention is to provide a semiconductor structure with a single diffusion break, including: a substrate with a plurality of fins protruding from the substrate and extending in a first direction, and a first region and a second region are defined on the substrate, and the first region and the second region are adjacent in the first direction and are provided with respective fins; a shallow trench isolation surrounding the fins on the substrate; a plurality of gates extending over the fins in a second direction; a dummy gate on the shallow trench isolation between the first region and the second region and extending in the second direction, and the dummy gate and the gates are spaced apart in the first direction; a plurality of first conductive patterns extending over the fins in the second direction and connected with the fins, and the first conductive patterns, the dummy gates and the gates are spaced apart alternately in the first direction; at least one second conductive pattern located on and connected with the dummy gate; and at least one dummy via located on and connected with the second conductive pattern.

Another aspect of the present invention is to provide a method of manufacturing a single diffusion break structure, including: providing a substrate, a first region and a second region are defined on the substrate, and the first region and the second region are adjacent in a first direction; forming a plurality of fins on the substrate, and the fins protrude from the substrate and extend in the d first direction; forming a shallow trench on the fins between the first region and the second region; filling the shallow trench with a first dielectric layer to form a first shallow trench isolation; forming a dummy gate on the first shallow trench isolation between the first region and the second region, and the dummy gate extends in a second direction; forming at least one second conductive pattern on the dummy gate; and forming at least one dummy via on the at least one second conductive pattern.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic layout diagram of a semiconductor circuit with a single diffusion break (SDB) structure in prior art;

FIG. 2 is a schematic cross-sectional view taken along the section line A-A′ in FIG. 1;

FIG. 3 is a schematic layout diagram of a semiconductor structure with a single diffusion break in accordance with an embodiment of the present invention;

FIG. 4 is a schematic cross-sectional view taken along the section line Y-Y′ in FIG. 3;

FIG. 5 is a schematic layout diagram of a semiconductor structure with a single diffusion break in accordance with another embodiment of the present invention;

FIG. 6 is a schematic cross-sectional view taken along the section line Y-Y′ in FIG. 5;

FIG. 7 is a schematic cross-sectional view taken along the section line X-X′ in FIG. 3 and FIG. 5;

FIGS. 8-10 are schematic cross-sectional views of a process of manufacturing a semiconductor structure with a single diffusion break in accordance with an embodiment of the present invention; and

FIGS. 11-13 are schematic cross-sectional views of a process of manufacturing a semiconductor structure with a single diffusion break in accordance with another embodiment of the present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

Reference will now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something). Further, spatially relative terms, such as “beneath,” “below,” “lower,” “above,” “upper,” and the like, may be used herein for ease of description to describe one element or feature relationship to another element(s) or feature(s) as illustrated in the figures.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or through holes are formed) and one or more dielectric layers.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. Additionally, the term “based on” may be understood as not necessarily intended to convey an exclusive set of factors, but may allow for the presence of other factors not necessarily expressly described, again depending at least in part on the context.

It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

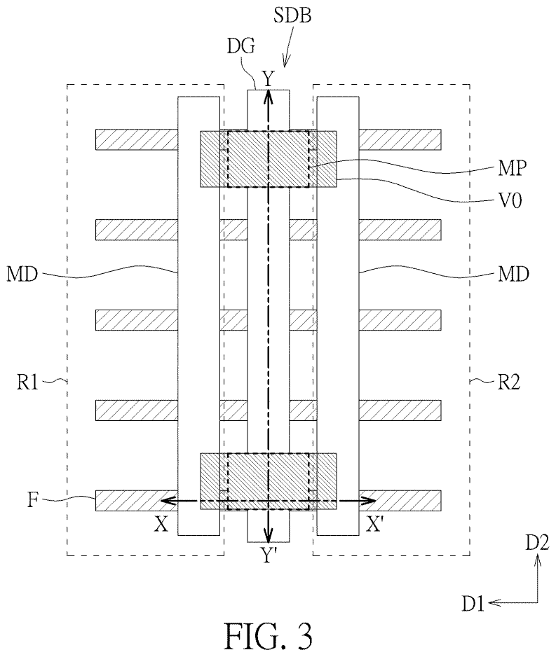

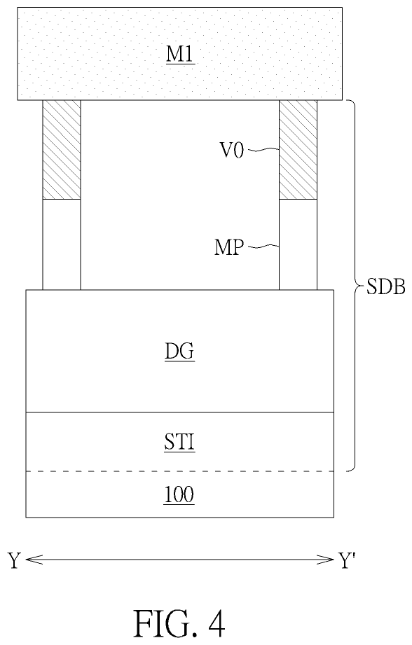

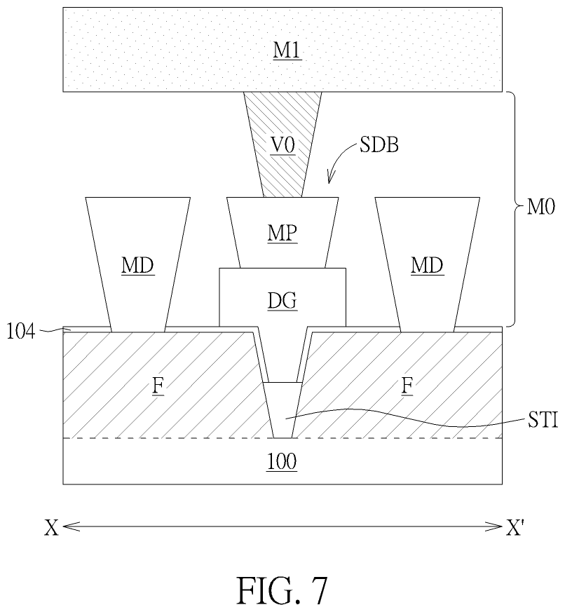

First, please refer to FIGS. 3, 4 and 7 at the same time, wherein FIG. 3 is a schematic layout diagram of a semiconductor structure with a single diffusion break (SDB) in accordance with an embodiment of the present invention. FIG. 4 is a schematic cross-sectional view taken along the section line Y-Y′ in FIG. 3, and FIG. 7 is a schematic cross-sectional view taken along the section line X-X′ in FIG. 3. These illustrations allow readers to fully understand the overlapping relation of the planar layout pattern of the semiconductor structure of the present invention, as well as the relative position and connection relation of every component in the vertical direction. As shown in the figure, the single diffusion break structure SDB of the present invention includes a plurality of fins F. These fins F can be extensions of a substrate 100, which protrude upwardly from the surface of the substrate 100 and have a longitudinal axis extending in a first direction D1, while the fins F are spaced apart in a second direction D2. The first direction D1 is preferably perpendicular to the second direction D2. The material of fins F and substrate 100 may be monocrystalline silicon. In the embodiment of the present invention, the fins F may be located in an active block defined on the substrate 100, and every active block is provided with individual fin group and may be further divided into multiple cells, as the first region R1 and second region R2 shown in the figure. Each cell region may be provided with different operating voltages, physical characteristics or specific functions, and can be electrically isolated by the single diffusion break structure SDB.

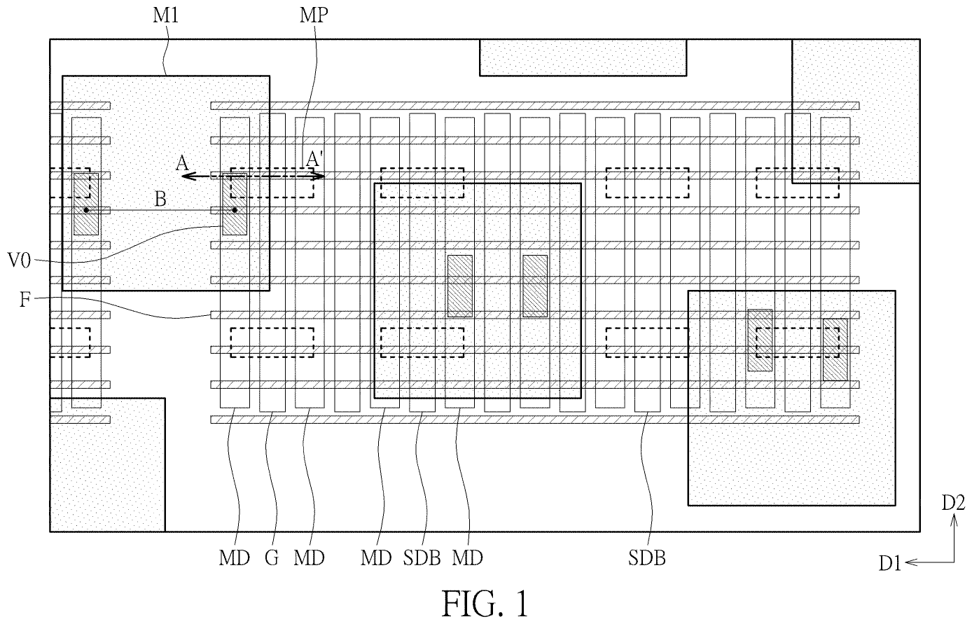

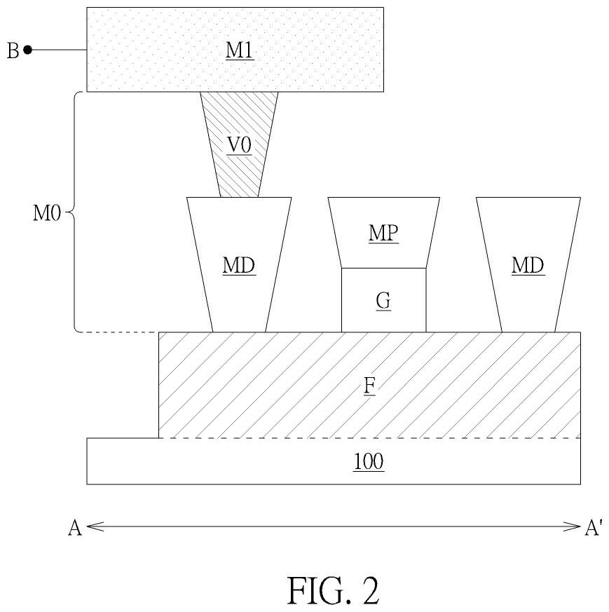

In the embodiment, the semiconductor structure of the present invention also has components like the gate G and the first conductive pattern MD (also known as metal zero over oxide (M0OD), abbreviated hereinafter as MD) as shown in FIG. 1, which are spaced apart alternately in the first direction D1 and with a longitudinal axis extending over the fins F in the second direction D2. However, for the simplicity of illustration and to avoid obscuring the focus of the present invention, only components and features in the vicinity of the single diffusion break structure SDB will be shown in the figures. As shown in FIG. 3, the single diffusion break structure SDB is provided with a dummy gate DG, with its pattern generally the same as the gate G set between the two first conductive patterns MD closest to the boundary. The material of dummy gate DG may be doped polycrystalline silicon. Furthermore, as can be seen from FIG. 7, different from the conventional gate G, the dummy gate DG is generally set on a shallow trench isolation STI. More specifically, it is set on the shallow trench isolation STI between two cell regions (ex. first region R1 and second region R2), with a longitudinal axis extending in the second direction D2 and with both sides crossing over the ends of the fins F in the two regions. A gate oxide layer 101 is formed between the dummy gate DG and the fin F to isolate them. As can be seen from FIG. 4, the dummy gate DG in the Y-Y′ cross-section (that is, on the boundary between the two regions) is completely located on the shallow trench isolation STI and is directly connected therewith. The shallow trench isolation STI may be made of silicon oxide or silicon nitride, disposed on the substrate 100 and surrounds the fins F to isolate different device areas in the circuit, preventing electrical interference between different devices or components. In the embodiment, the areas exposed or protruding from the shallow trench isolation STI (i.e., the fins F) may also be referred as oxide definition patterns (OD) or active areas (AA).

Refer still to FIGS. 3, 4 and 7. In the structure of the present invention, components like a second conductive pattern MP (also known as the metal zero over polysilicon (M0OP), abbreviated hereinafter as MP) and dummy zeroth via V0 are further provided on the dummy gate DG of the single diffusion break structure SDB. In this embodiment, the second conductive pattern MP may be disposed on both ends of the dummy gate DG in the second direction D2 and be directly connected to the dummy gate DG. The second conductive pattern MP is preferably of the same height as the adjacent first conductive pattern MD, and can be made of metal material, such as tungsten (W), aluminum (Al), copper (Cu), titanium (Ti), etc. In some embodiments, the second conductive pattern MP may be connected or integrated with the first conductive pattern MD, but is not limited thereto. In this embodiment, two dummy vias V0 are disposed respectively on both ends of the second conductive pattern MP and are directly connected thereto. The dummy gate DG will be further connected to a first metal layer M1 of the upper semiconductor BEOL (back-end-of-line) interconnect circuit through the second conductive pattern MP and the dummy via V0. The material of the dummy via V0 can be the same as the first conductive pattern MD and the second conductive pattern MP, such as tungsten (W), aluminum (Al), copper (Cu), titanium (Ti), etc. As shown in FIG. 7, from a perspective of vertical structure, the aforementioned first conductive pattern MD, second conductive pattern MP and dummy via V0 can be regarded as a zeroth metal layer M0 between the semiconductor FEOL (front-end-of-line) active area and the semiconductor BEOL first metal layer M1, and the shallow trench isolation STI, the dummy gate DG, the second conductive pattern MP and the dummy via V0 in the figure can be regarded as the single diffusion break structure SDB of the present invention.

It should be noted that in the present invention, compared with conventional skill shown in FIG. 1, the dummy via V0 originally disposed on the first conductive pattern MD is changed to be disposed on the second conductive pattern MP in a single diffusion break structure SDB. With this design, the dummy via V0 once disposed on the first conductive pattern MD and forming a conductive path is instead disposed on the single diffusion break structure SDB. In this way, although it is connected to the first metal layer M1, since the fins F in the two regions below are isolated by the shallow trench isolation STI and the gate oxide layer 104, no channel will be formed to cause current leakage between different regions.

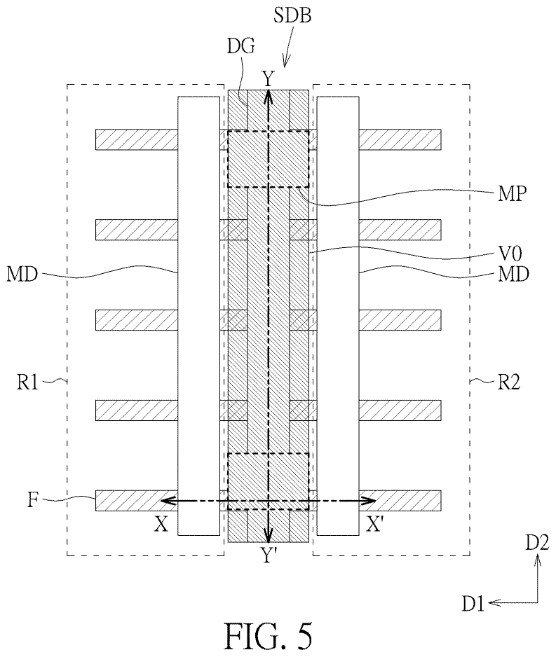

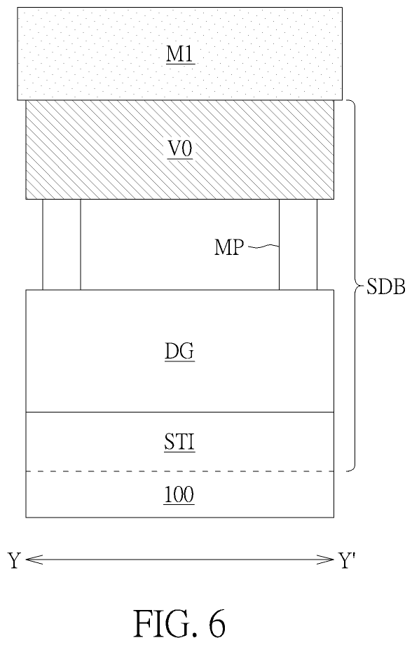

Please refer now to FIGS. 5 and 6 at the same time, wherein FIG. 5 is a schematic layout diagram of a semiconductor structure with a single diffusion break in accordance with another embodiment of the present invention, and FIG. 6 is a schematic cross-sectional view taken along the section line Y-Y′ in FIG. 5. The structure of this embodiment is similar to the previous embodiment, with only difference that the shape of dummy via V0 originally disposed on the second conductive pattern MP is changed into a long bar (referred hereinafter as the dummy vertical interconnect bar V0). As shown in FIG. 5, in this embodiment, the longitudinal axis of the dummy vertical interconnect bar V0 extends in the second direction D2, and the dummy vertical interconnect bar V0 substantially overlaps the dummy gate DG below in the vertical direction and is connected with the second conductive pattern MP below located at both ends of the dummy gate DG. The dummy gate DG is connected upwardly to the upper first metal layer M1 of the semiconductor BEOL circuit through the two second conductive patterns MP and the dummy vertical interconnect bar V0.

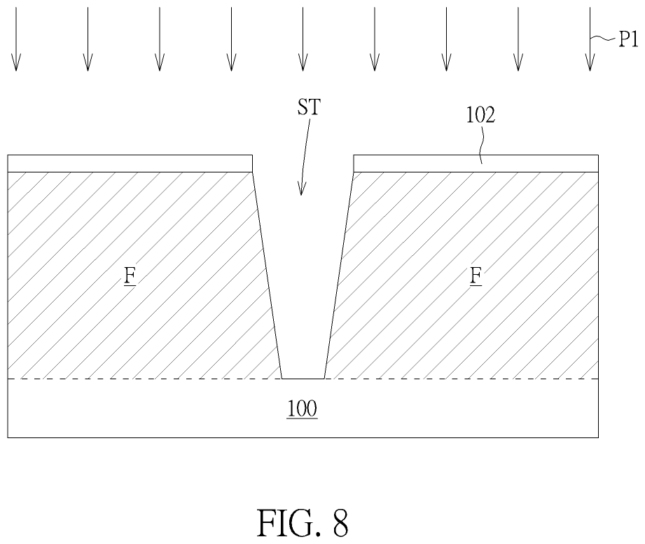

After describing the semiconductor structure of the present invention, the following embodiments will illustrate the process of manufacturing the semiconductor structure with single diffusion break according to the embodiment of the present invention with reference to FIGS. 8 to 10 sequentially. The cross-sections in FIGS. 8 to 10 are taken along a section line similar to the section line X-X′ in FIG. 3, which cuts through a single fin F and a single diffusion break structure in the middle along the first direction D1.

First, please refer to FIG. 8. A substrate 100 is provided as a basis for the semiconductor structure of the present invention. A fin F is formed on the substrate 100 in advance. In the embodiment, the steps of manufacturing the fin F are as follows, which may include forming a pad oxide layer 102 first on the substrate 100 by directly oxidizing the silicon-based substrate 100 through thermal oxidation. Next, a photolithography process is performed to pattern the substrate 100, so that the fins F protruding from the surface of the substrate 100 can be formed on the substrate 100. A deposition process, such as a flowable chemical vapor deposition (FCVD) process, is then performed to form a shallow trench isolation (not shown), ex. a silicon oxide layer, around the fin F. The fin F is an active area defined by the shallow trench isolation. The aforementioned steps of forming the fins F and the shallow trench isolation are conventional processes, and are not specifically shown in the figure in order to avoid obscuring the focus of the present invention. After the fin F is formed, another photolithography process P1 is then performed to pattern the formed fin F, thereby forming a shallow trench ST on the fin F, as shown in FIG. 8. In the embodiment, the shallow trench ST may be located between two cell regions, such as between the first region R1 and the second region R2 as shown in FIG. 3, which separates the original single fin F (ex. a fin in an active block) into two fins F located in two different cell regions. The depth of the shallow trench ST may be, but not limited to, higher than, equal to or lower than the bottom of the original fin F. The pad oxide layer 102 can protect the fin F and the substrate 100 during the photolithography process above, preventing unnecessary areas from being damaged by etching, and ensure the accuracy and uniformity of the photolithography process.

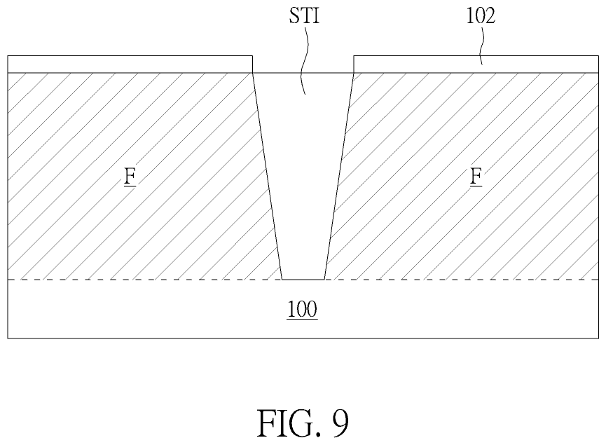

Please refer to FIG. 9. After the shallow trench ST is formed, another shallow trench isolation STI is formed in the shallow trench ST. In the embodiment of the present invention, the process of forming the shallow trench isolation STI may include performing a deposition process, ex. an FCVD process, to fill the shallow trench ST with a dielectric. The dielectric is preferably different from the aforementioned shallow trench isolation around the fin F, such as silicon nitride. Thereafter, an etch back process is performed to remove the dielectric outside the shallow trench ST, thereby forming a shallow trench isolation STI only located in the shallow trench ST. In this etch back step, since the material (silicon oxide) of the shallow trench isolation around the fin F has a significant etching selectivity ratio with the material (silicon nitride) of the shallow trench isolation STI in the shallow trench ST, the etch back process will not damage the shallow trench isolation around the fin F. It should be noted that in this embodiment, the shallow trench isolation STI in the shallow trench ST and the general shallow trench isolation defining the active area around the fin F are formed in different steps and are preferably made of different materials. The general shallow trench isolation around the fin F is used to define the fin F, while the shallow trench isolation STI in the shallow trench ST is used as a part of the single diffusion break structure SDB of the present invention to isolate the two fins F in different cell regions on both sides.

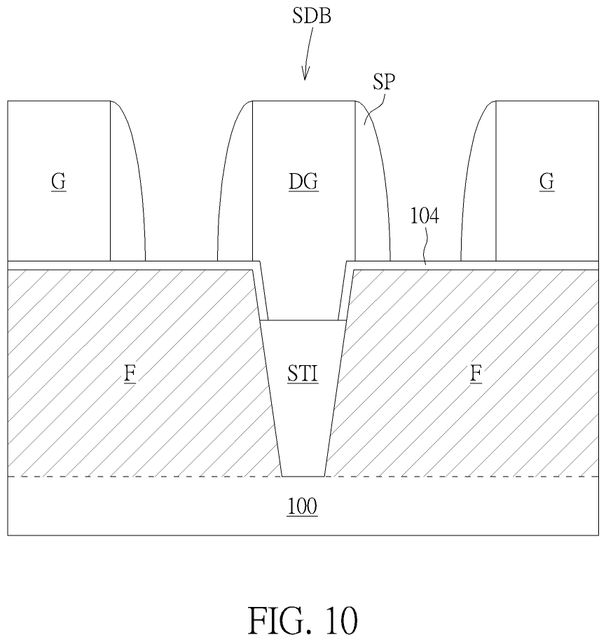

Please refer to FIG. 10. After the shallow trench isolation STI is formed, a doping process may then be performed to form the well required by the device in the fin F. Thereafter, an etch back process is performed to reduce the height of the aforementioned shallow trench isolation, including the general shallow trench isolation around the fin F and the shallow trench isolation STI in the shallow trench ST, to make the fin F protruding from the shallow trench isolation for manufacturing fin field effect transistors (FinFETs). The aforementioned pad oxide layer 102 can also be removed in this step. As shown in FIG. 10, after the fin F protrudes, a gate oxide layer 104 may be formed on the exposed surface of the fin F, which may be formed by directly oxidizing the exposed silicon-based fin F through thermal oxidation or through a CVD process. Afterwards, components such as the dummy gate DG and gate G are formed on the fin F. The plan layout patterns of the dummy gate DG and gate G is shown in FIG. 1, which are spaced apart in the first direction D1 and have their longitudinal axis extending over a plurality of the fins F in the second direction D2, wherein the dummy gate DG is generally disposed on the aforementioned shallow trench isolation STI, and more specifically, disposed on the shallow trench isolation STI between two cell regions (ex. the first region R1 and the second region R2 in FIG. 3), with its both sides respectively spanning over the ends of the fins F in the two regions. The dummy gate DG and the gate G can be formed by depositing a polycrystalline silicon layer on the fin F through a CVD process and then patterning it through a photolithography process. In addition, spacers SP can be formed on the sidewalls of the dummy gate DG and the gate G to provide a protection effect and define the source/drain regions at both sides of the device. The material of the spacer SP may be silicon oxide, silicon nitride or a multilayered structure thereof. After the dummy gate DG, gate G and spacers are formed, the first conductive pattern MD, the second conductive pattern MP and the dummy via V0 in the semiconductor structure of the present invention can be formed subsequently. Since the processes of manufacturing these components are conventional skills, they will not be described herein in detail to avoid obscuring the focus of the present invention.

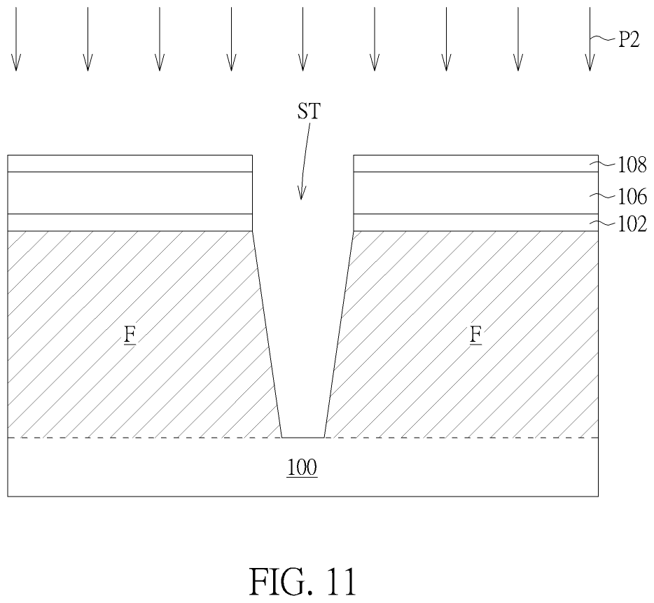

Please refer now to FIGS. 11 to 13 in sequence, which illustrate a process of manufacturing a semiconductor structure with a single diffusion break according to another embodiment of the present invention. The difference between this embodiment and the previous embodiment is that the shallow trench ST is formed in different stages. General fin patterning process may have multiple cutting processes to cut out the required fin patterns. For example, a first cutting process is performed to cut off the head and tail parts of a spacer around a mandrel to form multiple fins, and a second cutting process is then performed to remove other unnecessary fin parts to define the fins located in each active block, ex. the fin patterns in FIG. 1. On this basis, as shown in FIG. 11, in this embodiment, a photolithography process P2 is performed to pattern the formed fins F, so that the shallow trench ST will be formed on the fin F. In the embodiment, the photolithography process P2 may be performed after the aforementioned first cutting process and before the second cutting process. The shallow trench ST can be located between two cell regions, such as between the first region R1 and the second region R2 as shown in FIG. 3, which separates the original single fin F (ex. the fin in an active block) into two fins F located respectively in two different cell regions. The depth of the shallow trench ST can be higher than, equal to or lower than the bottom of the original fin F, but is not limited thereto. In this embodiment, a pad oxide layer 102, a pad nitride layer 106 and a plasma-enhanced oxide layer 108 are formed sequentially on the top surface of the fin F, wherein the pad oxide layer 102 may function as a buffer layer between the pad nitride layer 106 and the fin F, and the pad nitride layer 106 can function as a stop layer in the planarization step (ex. CMP) of manufacturing the shallow trench isolation structure. The plasma-enhanced oxide layer 108 serves as an isolation layer to prevent the silicon nitride layer from reacting with other layer structures.

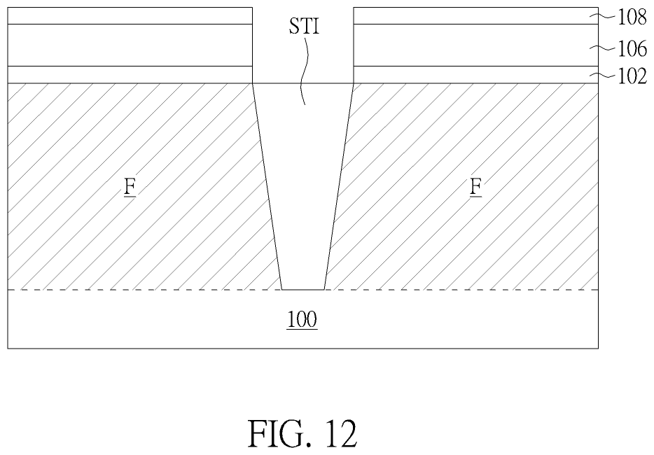

Please refer to FIG. 12. After the fin F and the shallow trench ST are formed, a deposition process, ex. an FCVD process, can be performed to fill the shallow trench ST with a dielectric. In this embodiment, the dielectric can simultaneously surround the fin F and fill the shallow trench ST. Afterward, an etch back process is performed to remove the dielectric above the height of the top surface of the fin F and outside the shallow trench ST, thereby forming a shallow trench isolation STI around the fin F and in the shallow trench ST. In this embodiment, different from the previous embodiments, the shallow trench isolation STI in the shallow trench ST is integrated with the shallow trench isolation defining the active area around the fin F, and they have the same material (ex. silicon oxide) and are formed in the same process, wherein the shallow trench isolation STI in the shallow trench ST functions as part of the single diffusion break structure of the present invention to isolate the fins F in different cell regions on both sides.

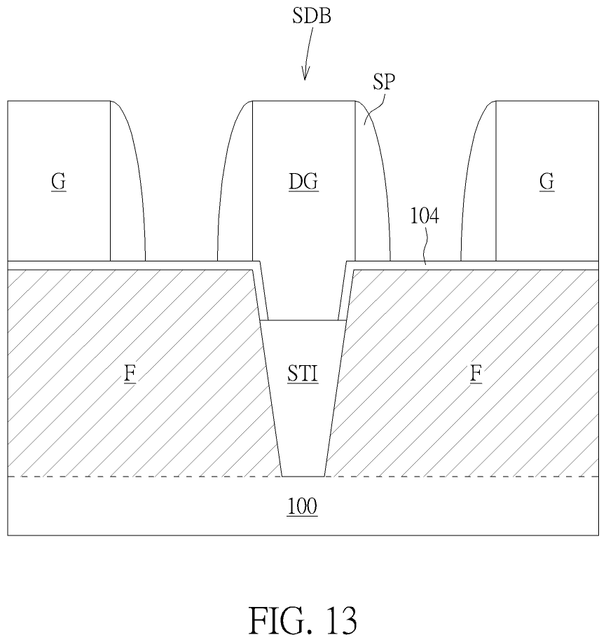

Please refer to FIG. 13. After the shallow trench isolation STI is formed, similarly, a doping process may then be performed to form the well required for the device in the fin F. Thereafter, an etch back process is performed to remove the aforementioned part of the shallow trench isolation STI, including the general shallow trench isolation around the fin F and the shallow trench isolation in the shallow trench ST, so that the height of the shallow trench isolation STI is reduced to protrude the fin F, for subsequent process of manufacturing fin field effect transistors (FinFETs). The aforementioned pad oxide layer 102 may also be removed in this step. As shown in FIG. 13, after the fin F is protruded, a gate oxide layer 104 may then be formed on the exposed surface of the fin F, which can be formed by directly oxidizing the exposed silicon-based fin F through thermal oxidation or through a CVD process. Afterwards, components such as the dummy gate DG and gate G are formed on the fin F. The plan layout patterns of the dummy gate DG and the gate G are shown in FIG. 1, which are spaced apart in the first direction D1 and have their longitudinal axis extending over a plurality of the fins F in the second direction D2, wherein the dummy gate DG is generally disposed on the aforementioned shallow trench isolation STI, and more specifically, disposed on the shallow trench isolation STI between two cell regions (ex. the first region R1 and the second region R2 in FIG. 3), with its both sides respectively spanning over the ends of the fins F in the two regions. In addition, spacers SP may be formed on the sidewalls of the dummy gate DG and gate G to provide protection and define the source/drain regions on both sides of the device. After the dummy gate DG, gate G and the spacers SP are formed, the first conductive pattern MD, the second conductive pattern MP and the dummy via V0 in the semiconductor structure of the present invention may be formed subsequently. Since the processes of manufacturing these components are conventional skills, they will not be described herein in detail to avoid obscuring the focus of the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure with a single diffusion break, comprising:
a substrate with a plurality of fins protruding from said substrate and extending in a first direction, and a first region and a second region are defined on said substrate, and said first region and said second region are adjacent in said first direction and are provided with respective said fins;
a shallow trench isolation surrounding said fins on said substrate;
a plurality of gates extending over said fins in a second direction;
a dummy gate on said shallow trench isolation between said first region and said second region and extending in said second direction, and said dummy gate and said gates are spaced apart in said first direction;
a plurality of first conductive patterns extending over said fins in said second direction and connected with said fins, and said first conductive patterns, said dummy gates and said gates are spaced apart alternately in said first direction;
at least one second conductive pattern located on and connected with said dummy gate; and
at least one dummy via located on and connected with said second conductive pattern.

2. The semiconductor structure with a single diffusion break of claim 1, wherein said first conductive patterns are of the same height as said at least one second conductive pattern.

3. The semiconductor structure with a single diffusion break of claim 1, wherein said at least one second conductive pattern is two said second conductive patterns respectively on both ends of said dummy gate.

4. The semiconductor structure with a single diffusion break of claim 3, wherein said at least one dummy via is two dummy vias respectively on said two second conductive patterns.

5. The semiconductor structure with a single diffusion break of claim 3, wherein said at least one dummy via is a dummy vertical interconnect bar extending in said second direction on said two second conductive patterns.

6. The semiconductor structure with a single diffusion break of claim 1, wherein none of said at least one dummy via is provided on said two first conductive patterns closest to said dummy gate in said first direction.

7. The semiconductor structure with a single diffusion break of claim 1, wherein said first conductive patterns are a metal zero pattern over oxide definition layer (MD), said dummy gate is made of polysilicon, said at least one second conductive pattern is a metal zero pattern over polysilicon (MP), said at least one dummy via is a zeroth via (V0) located in a zeroth metal layer, and said zeroth via is connected upwardly to said first metal layer.

8. The semiconductor structure with a single diffusion break of claim 1, wherein said dummy gate crosses over said fins in said first region and said second area on both sides.

9. A method of manufacturing a single diffusion break structure, comprising:
providing a substrate, a first region and a second region are defined on said substrate, and said first region and said second region are adjacent in a first direction;
forming a plurality of fins on said substrate, and said fins protrude from said substrate and extend in said first direction;
forming a shallow trench on said fins between said first region and said second region;
filling said shallow trench with a first dielectric layer to form a first shallow trench isolation;
forming a dummy gate on said first shallow trench isolation between said first region and said second region, and said dummy gate extends in a second direction;
forming at least one second conductive pattern on said dummy gate; and
forming at least one dummy via on said at least one second conductive pattern.

10. The method of manufacturing a single diffusion break structure of claim 9, wherein said step of forming said fins on said substrate comprise a first cutting process and a second cutting process, and said step of forming said shallow trench is performed after said second cutting process.

11. The method of manufacturing a single diffusion break structure of claim 10, further comprising depositing a second dielectric layer around said fins after said second cutting process and before forming said shallow trench, thereby forming a second shallow trench isolation.

12. The method of manufacturing a single diffusion break structure of claim 11, further comprising performing an etch back process to remove parts of said first shallow trench isolation and said second shallow trench isolation after said first shallow trench isolation and said second shallow trench isolation are formed, so that heights of said first shallow trench isolation and said second shallow trench isolation are reduced to protrude said fins.

13. The method of manufacturing a single diffusion break structure of claim 9, wherein said step of forming said fins on said substrate comprises a first cutting process and a second cutting process, and said step of forming said shallow trench is performed between said first cutting process and said second cutting process.

14. The method of manufacturing a single diffusion break structure of claim 13, further comprising forming said first dielectric layer around said fins and in said shallow trench after said second cutting process.

15. The method of manufacturing a single diffusion break structure of claim 14, further comprising performing an etch back process after forming said first shallow trench isolation to remove part of said first shallow trench isolation, thereby reducing a height of said first shallow trench isolation to protrude said fins.
